(19) United States
(12) Patent Application Publication
(10) Pub. No.: US 2022/0148770 A1
(43) Pub. Date: May 12, 2022

(54) Method for adjusting resistance value of thin film resistance layer in semiconductor structure

(71) Applicant: United Semiconductor (Xiamen) Co., Ltd., Xiamen (CN)

(72) Inventors: Wei-Chun Chang, Taichung City (TW); Yunfei Fu, Shamen City (CN); You-Di Jhang, New Taipei City (TW); Chin-Chun Huang, Hsinchu County (TW); WEN YI TAN, Xiamen (CN)

(21) Appl. No.: 17/115,803

(22) Filed: Dec. 9, 2020

(30) Foreign Application Priority Data
Nov. 11, 2020 (CN) 202011251737.2

(51) Int. Cl. H01C 17/075; H01C 7/00; C23C 16/04; C23C 16/34; C23C 16/505

(52) U.S. Cl. CPC H01C 17/075; H01C 7/006; C23C 16/505; C23C 16/345; C23C 16/04

(57) ABSTRACT

The invention provides a method for adjusting the resistance value of a thin film resistor layer in a semiconductor structure, which comprises forming the thin film resistor layer, the material of the thin film resistor layer comprises titanium nitride, and the thin film resistor layer has an original resistance value, a mask layer with tensile force is formed above the thin film resistor layer, and the mask layer with tensile force changes a lattice size of the thin film resistor layer, so that the lattice size of the thin film resistor layer becomes larger and the original resistance value of the thin film resistor layer is reduced.

### BACKGROUND OF THE INVENTION

### 1. Field of the Invention

The present invention relates to the field of semiconductors, in particular to a method for adjusting the resistance of a thin film resistor layer in a semiconductor structure by stress.

### 2. Description of the Prior Art

In the field of semiconductor fabrication, polysilicon material has been conventionally used to form the gates of metal-Oxide-Semiconductor Field-Effect (MOSFET) transistors. However, polysilicon materials have some drawbacks: the resistance of a polysilicon gate is higher than most of any metal materials, and the conductivity rate of the polysilicon gate is therefore lower than metal wires. In order to compensate for this disadvantage, the polysilicon gate usually undergoes a silicide process to simultaneously reduce the contact resistance and the parasitic resistance (Rp), so that the conductivity rate of the polysilicon gate is improved to an acceptable range.

In the trend to replace the polysilicon gates with metal gates, those integrated passive devices that used to be made of polysilicon are also replaced with metal materials. Similarly to the formation process of the active devices, passive devices such as thin film resistor are fabricated by integrating the formation of the metal layer and the dielectric layer, the photolithography process, and the etching process.

### SUMMARY OF THE INVENTION

The present invention provides a method for adjusting the resistance of a thin film resistor layer in a semiconductor structure, the method includes the following steps: Firstly, a thin film resistor layer is formed, that material of the thin film resistor layer comprises titanium nitride, and the thin film resistor layer has an original resistance value, and a mask layer with tensile force is formed on the thin film resistor layer, and the mask layer with tensile force changes a lattice size of the thin film resistor layer, so that a lattice size of the thin film resistor layer becomes larger, and the original resistance value of the thin film resistor layer is reduced.

One feature of the present invention is to propose a method for manufacturing thin film resistors which is different from the conventional technology. In particular, provides a method for adjusting the resistance value of a thin film resistance layer. In the conventional process, if the resistance value of the thin film resistance layer needs to be adjusted, the thickness of the thin film resistance layer is usually increased or decreased to change the resistance value of the thin film resistance layer. The present invention provides another method to increase the internal lattice size of the thin film resistor layer and reduce the resistance of the thin film resistor layer by changing the stress of the mask material layer covering the thin film resistor layer (increasing the tensile force). The applicant found that the uniformity of the whole resistance of the thin film resistor layer formed by this process is higher, which is beneficial to improve the quality of the thin film resistor layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 are schematic diagrams illustrating a thin film resistor structure according to a first preferred embodiment of the present invention, wherein

FIG. 2 is a schematic drawing in a step subsequent to FIG. 1,

FIG. 3 is a schematic drawing in a step subsequent to FIG. 2,

FIG. 4 is a schematic drawing in a step subsequent to FIG. 3,

FIG. 5 is a schematic drawing in a step subsequent to FIG. 4, and

FIG. 6 is a schematic drawing in a step subsequent to FIG. 5.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Please refer to FIG. 1˜6, FIGS. 1-6 are schematic diagrams illustrating a thin film resistor structure according to the first preferred embodiment of the present invention. Please note that the figures are only for illustration and may not be to scale. The scale may be further modified according to different design considerations. At first, as shown in FIG. 1, a substrate 100 is provided, a semiconductor region 102 and a resistor region 104 are on the substrate 100, and a plurality of STI (shallow trench isolation) 106 is then formed on the substrate 100 within the semiconductor region 102 and the resistor region 104. The substrate 100 may be a semiconductor substrate such as silicon substrate, epitaxial silicon substrate, silicon germanium substrate, silicon carbide substrate or silicon-on-insulator (SOI).

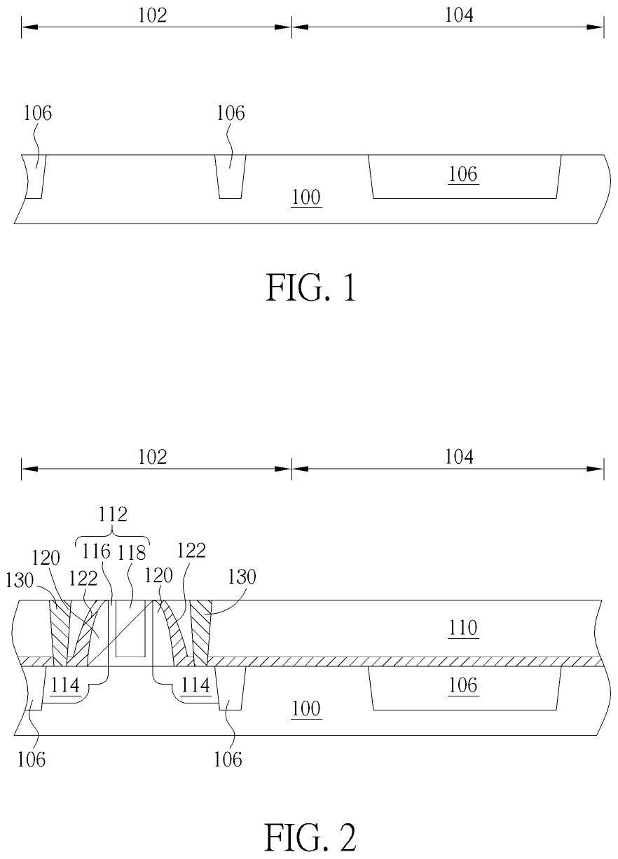

A polysilicon gate (not shown) is formed within the semiconductor region 102 as a dummy gate, and after a light doped drain (LDD), a spacer, a source/drain and a dielectric layer are formed, the polysilicon gate is replaced with a metal gate by a gate replacement process and a contact plug process. A bottom ILD (inter layer dielectric) 110 is entirely formed on the substrate 100 by a planarization process such as CMP (chemical mechanical polishing). After that, a plurality of first contacts 130 is formed in the bottom ILD 110 within the semiconductor region 102. Up to present step, as shown in FIG. 2, the semiconductor region 102 comprises at least a metal gate structure 112, and a top surface of the metal gate 112 is on the same level as a top surface of the bottom ILD 110, each top surface of the first contacts 130 is also on the same level as the top surface of the bottom ILD 110, wherein the type of the first contact 130 is not limited, it may be a pole contact or a slot contact.

The metal gate 112 includes a high-k layer 116 and at least a metal layer 118, wherein the high-k layer 116 is disposed between the substrate 100 and the metal layer 118, it may selected from a group comprising hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrxTi₁-xO₃, PZT) and barium strontium titanate (BaxSr₁-XTiO₃, BST). The metal layer 118 may be adjusted according to the metal gate 112 for PMOS or NMOS use, each of them having specific bottom barriers, work function layer, top barriers and main conductive layer. Moreover, the first contact 130 may be formed during the gate replacement process simultaneously, so that the first contact 130 and the metal gate 112 have the same materials in the work function layer and the main conductive layer, such as aluminum (Al), tungsten (W), copper (Cu), titanium aluminide (TiA1), titanium (Ti), titanium nitride (TiN), tantalum (Ta), Tantalum nitride (TaN) and titanium aluminum oxide (TiAlO). Besides, the spacer 120 may be a single layer structure or a multilayer structure formed by materials such as silicon nitride or silicon oxide, and at least a first doping region 114 formed in the substrate 100 at least one side of the metal gate 112, the doping region 114 may include an epitaxial layer such as a silicon germanium epitaxial layer or a silicon carbide epitaxial layer, and a metal silicide (not shown) may be further formed on the doping region 114 to improve the contact performances. In addition, a CESL (contact etch stop layer, CESL) 122 may be formed between the substrate 100 and the bottom ILD 110.

It is worth noting that the embodiment is described with a high-k gate last process, but not limited thereto, the present invention may also use a high-k first gate last process, a high-k gate first process or a polysilicon gate process, and the related technologies are well known by users skilled in the technology, not redundantly described here.

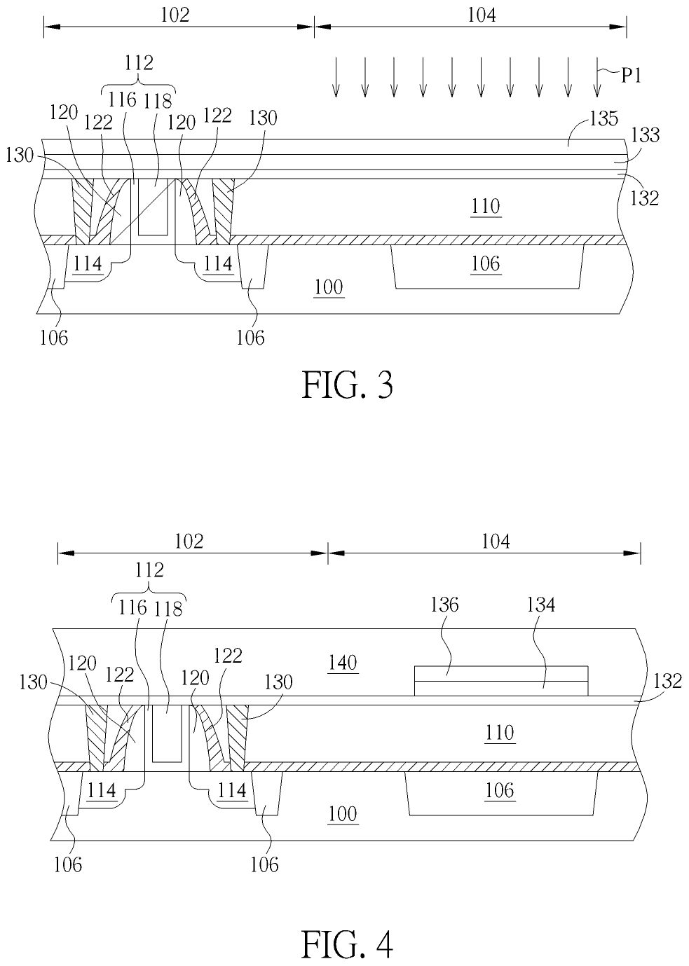

Then, as shown in FIG. 3, a second etching stop layer 132, a thin film resistive material layer 133 and a mask material layer 135 are formed in sequence. A (nitrogen doped carbide, NDC) layer can be used as the second etching stop layer 132 to protect the underlying devices during the etching step. The thin film resistive material layer 133 can be made of barrier materials such as titanium nitride or tantalum nitride. The mask material layer 135 can be made of silicon nitride to protect the lower thin film resistance material layer 133 from moisture and oxygen.

Referring to FIG. 3, the applicant found that if one or more additional steps P1 are performed in the process of forming the mask material layer 135, the mask material layer 135 with tensile force can be formed. The mask material layer 135 with tensile force covers the thin film resistance material layer 133. According to the experimental results, the resistance value of the thin film resistance material layer 133 can be reduced.

In the present invention, there are several methods for forming the mask material layer 135 with tensile force, one of which is to introduce silane (SiH₄) gas during the process, another method is to introduce ammonia gas (NH₃) gas during the process, and the other is to perform a high frequency radio frequency (HFRF) step simultaneously during the process of forming the mask material layer 135. Taking the applicant's experimental results as an example, if silane gas is introduced, the gas flow rate is about 50 sccm-150 sccm, if ammonia gas is introduced, the gas flow rate is about 500 sccm-1500 sccm, and if HFRF step is performed, the process energy is about 150 W-450 W. If the above conditions are met, a mask material layer with sufficient tensile force (more than 100 Mpa) will be formed, but the above parameters are only the examples of the present invention, and the above parameters can be adjusted according to actual requirements. In addition, the mask material layer 135 of the present invention can be formed by physical vapor deposition (PVD), chemical vapor deposition (CVD) or atomic layer deposition (ALD), and the present invention is not limited thereto.

According to the applicant's experimental results, the mask material layer 135 with tensile force covers the thin film resistance material layer 133, and compared with the mask material layer 135 without tensile force (i.e., without additional step P1), the resistance of the thin film resistance material layer 133 in the present invention can be reduced. Taking this embodiment as an example, the original surface resistance value of the thin film resistive material layer 133 measured by the applicant is about 600±10 ohm/sq (i.e., the resistance value per square unit area), and after the mask material layer 135 with a tensile force in the range of about 100 MPa to 500 MPa is formed to cover the thin film resistive material layer 133, the surface resistance value of the thin film resistive material layer 133 measured by the applicant is reduced to 580±10 ohm/sq.

In addition, according to the applicant's experiment, when the mask material layer 135 with tensile force is covered on the thin film resistance material layer 133, it will also change the lattice size in the thin film resistance material layer 133. For example, before the mask material layer 135 with tensile force is formed, the original lattice size in the thin film resistive material layer 133 is measured to be about 0.4241 nm, and after covering the mask material layer 135 with tensile force on the thin film resistive material layer 133, the lattice size in the thin film resistive material layer 133 will increase.

After the above steps are completed, as shown in FIG. 4, the mask material layer 135 and the thin film resistance material layer 133 are etched simultaneously by photolithography and etching processes to form a stacked thin film resistance layer 134 (i.e., the thin film resistance material layer 133 left after etching) and a mask layer 136 (i.e., the mask material layer 135 left after etching) on the surface of the second etching stop layer 132 of the resistor region 104.Since the thin film resistor material layer 133 and the protective material layer 135 are patterned and etched simultaneously, the area of the thin film resistor layer 134 is equal to the area of the mask layer 136, and the sidewall of the mask layer 136 is flushed with the sidewall of the thin film resistor layer 134.

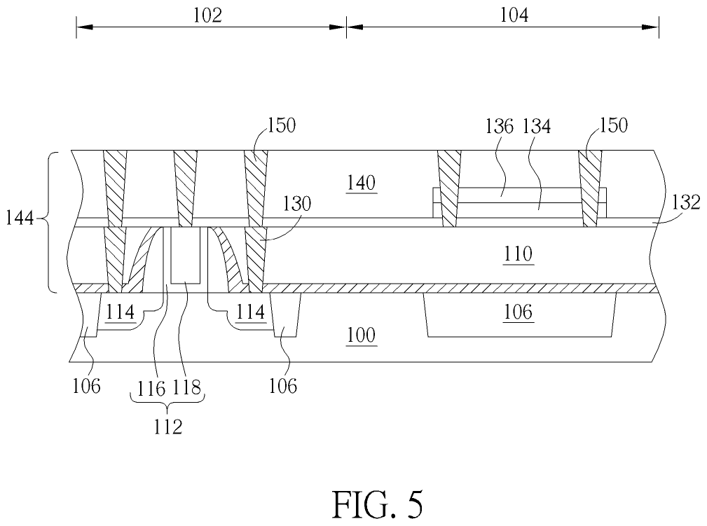

As shown in FIG. 5, a flat top ILD 140 is formed on the bottom ILD, which covers the mask layer 136. A plurality of second contacts 150 is then formed in the top ILD 140 within the semiconductor region 102 and the resistor region 104. It is worth noting that each second contact 150 within the resistor region 104 penetrates the mask layer 136 and the thin film resistor layer 134 so as to touch a surface of the second etching stop layer 132; and each second contact 150 within the semiconductor region 102 penetrates the second etching stop layer 132 and is electrically connected to the metal gate 112 or the first contacts 130. Each surface of the second contacts 150 is on the same level as surfaces of the top ILD 140. The thin film resistor layer 134 is disposed between the bottom ILD 110 and the top ILD 140, the bottom ILD 110 and the top ILD 140 may be a SiO₂ layer, forming a dielectric layer 144.

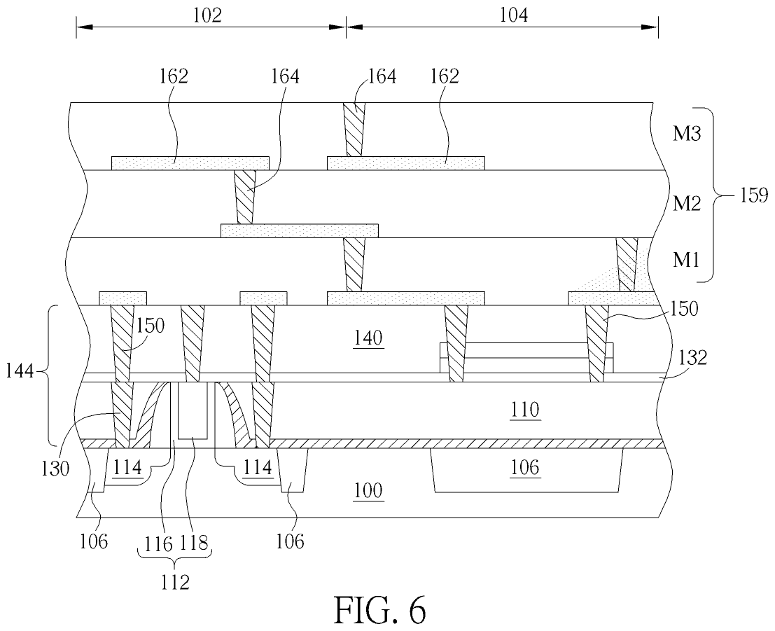

Afterwards, as shown in FIG. 6, after the top ILD 140 and the bottom ILD 110 are formed, an interconnection layer may be formed on the dielectric layer 144, such as an IMD (inter metal dielectric) 159 wherein the IMD 159 further comprises at least a metal trace 162 formed by copper or aluminum, such as a first metal layer (M1), a second metal layer (M2), a third metal layer (M3) . . . an n^{th} metal layer (Mn) and a via plug 164 in the IMD 159 to electrically connect the thin film resistor structure to other semiconductor elements.

It is worth noting that in this embodiment, although the metal gate 112 is not formed in the resistor region 104, however, in other embodiments of the present invention, the metal gate 112 or a dummy gate may be formed right below the thin film resistance layer 134 in the resistor region 104. It can be used as an element or a supporting structure, and the above structures are also within the scope of the present invention.

One feature of the present invention is to propose a method for manufacturing thin film resistors which is different from the conventional technology. In particular, provides a method for adjusting the resistance value of a thin film resistance layer. In the conventional process, if the resistance value of the thin film resistance layer needs to be adjusted, the thickness of the thin film resistance layer is usually increased or decreased to change the resistance value of the thin film resistance layer. The present invention provides another method to increase the internal lattice size of the thin film resistor layer and reduce the resistance of the thin film resistor layer by changing the stress of the mask material layer covering the thin film resistor layer (increasing the tensile force). The applicant found that the uniformity of the whole resistance of the thin film resistor layer formed by this process is higher, which is beneficial to improve the quality of the thin film resistor layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for adjusting the resistance of a thin film resistor layer in a semiconductor structure, comprising:
forming a thin film resistor layer, wherein that material of the thin film resistor layer comprises titanium nitride, and the thin film resistor layer has an original resistance value;
forming a mask layer with tensile force on the thin film resistor layer, and the mask layer with tensile force changes a lattice size of the thin film resistor layer, so that a lattice size of the thin film resistor layer becomes larger, and the original resistance value of the thin film resistor layer is reduced.

2. The method according to claim 1, wherein the material of the mask layer comprises silicon nitride.

3. The method according to claim 1, wherein the method for forming the mask layer with tensile force comprises introducing silane (SiH₄) gas and ammonia gas (NH₃) and performing a high frequency radio frequency (HFRF) step in the process of forming the mask layer.

4. The method according to claim 3, wherein the high frequency radio frequency step ranges from 150 W to 450 W.

5. The method according to claim 3, wherein the flow rate of the silane ranges from 50 sccm to 150 sccm.

6. The method according to claim 3, wherein the flow rate of the ammonia gas ranges from 500 sccm to 1500 sccm.

7. The method according to claim 1, wherein before the mask layer with tensile force is formed, the thin film resistance layer has the original surface resistance value, and the range of the original surface resistance value is 600±10 ohms/sq.

8. The method according to claim 1, wherein after the mask layer with tensile force is formed, the thin film resistance layer has a new surface resistance value, and the range of the new surface resistance value is 580±10 ohms/sq.

9. The method according to claim 1, further comprising at least one contact structure passing through the mask layer with tensile force and electrically connected with the thin film resistor layer.

10. The method according to claim 1, wherein the tensile force of the mask layer with tensile force ranges from 100 Mpa to 500 MPa.
